(19) United States
(12) Patent Application Publication
(10) Pub. No.: US 2007/0187363 A1
(43) Pub. Date: Aug. 16, 2007

(54) SUBSTRATE PROCESSING APPARATUS AND SUBSTRATE PROCESSING METHOD

(75) Inventors: Hiromi OKA, Nirasaki-shi (JP); Akitaka Shimizu, Nirasaki-shi (JP); Shosuke Endoh, Nirasaki-shi (JP); Kazuki Denpoh, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/673,948

(22) Filed: Feb. 12, 2007

Related U.S. Application Data
(60) Provisional application No. 60/783,824, filed on Mar. 21, 2006.

(30) Foreign Application Priority Data
Feb. 13, 2006 (JP) 2006-035549
Sep. 13, 2006 (JP) 2006-248241

(51) Int. Cl. G01L 21/30; H01L 21/306; C23F 1/00; C23C 16/00

(52) U.S. Cl. 216/59; 118/715; 156/345.33; 156/345.34

(57) ABSTRACT

A substrate processing apparatus that enables a state of plasma over a substrate to be maintained in a desired state easily. A plasma processing apparatus 10 that has therein a camber 11, a stage 12, and a processing gas introducing nozzle 38 carries out etching on a wafer W. The chamber 11 houses the wafer W. The stage 12 is disposed in the chamber 11 and the wafer W is mounted thereon. The processing gas introducing nozzle 38 is a projecting body that projects out into the chamber 11, and has therein a plurality of processing gas introducing holes 56 that open out in different directions to one another.

### BACKGROUND OF THE INVENTION

1. Field of the Invention

The present invention relates to a substrate processing apparatus and a substrate processing method, and in particular relates to a substrate processing apparatus that introduces a processing gas into a processing chamber, and carries out plasma processing on a substrate using plasma produced from the introduced processing gas.

2. Description of the Related Art

A substrate processing apparatus that carries out plasma processing such as etching on a wafer as a substrate has a processing chamber in which the wafer is housed and inside which the pressure can be reduced, a processing gas introducing unit that introduces a processing gas into the processing chamber, and a lower electrode that applies radio frequency electrical power into the processing chamber (a processing space) into which the processing gas has been introduced, and also acts as a stage on which the wafer is mounted. In such a substrate processing apparatus, plasma is produced by the radio frequency electrical power from the introduced processing gas in the processing space, and the wafer is subjected to the plasma processing by the produced plasma.

The processing gas introducing unit is disposed such as to face the wafer mounted on the lower electrode, and so that the processing gas can be jetted uniformly toward the wafer, is constructed as a shower head having therein a large number of small-diameter gas introducing holes disposed scattered over a surface thereof facing the wafer.

In a substrate processing apparatus using such a shower head, the processing gas jetted out from a group of a plurality of the gas introducing holes that open out toward an outer peripheral portion of the wafer (hereinafter referred to as the “outer peripheral portion gas introducing hole group”) undergoes diffusion. As a result, it is difficult to control the flow of the processing gas jetted out from the whole of the surface of the shower head facing the wafer, and hence an etching rate (hereinafter referred to merely as “etch rate”) distribution over the wafer becomes ununiform.

In view of this, there has been developed a shower head in which the outer peripheral portion gas introducing hole group and a group of a plurality of the gas introducing holes opening out toward a central portion of the wafer (hereinafter referred to as the “central portion gas introducing hole group”) are connected to different processing gas supply lines to one another (see, for example, Japanese Laid-open Patent Publication (Kokai) No. 2004-193567). If this shower head is used, then the flow rate of the processing gas jetted out toward the outer peripheral portion of the wafer, and the flow rate of the processing gas jetted out toward the central portion of the wafer can be controlled independently, and as a result the state of the plasma over the wafer can be maintained in a desired state.

However, in a substrate processing apparatus that etches a polysilicon layer formed on a wafer, the space (gap) between the shower head and the lower electrode on which the wafer is mounted is relatively large, and hence the processing gas jetted out from the outer peripheral portion gas introducing hole group, and the processing gas jetted out from the central portion gas introducing hole group each undergo diffusion before reaching the wafer. As a result, even if the processing gas flow rates are controlled, maintaining the state of the plasma over the wafer in the desired state is difficult, and hence the etch rate distribution becomes ununiform, and thus producing the desired shape of grooves formed through etching is difficult.

### SUMMARY OF THE INVENTION

It is an object of the present invention to provide a substrate processing apparatus and a substrate processing method, which enable the state of plasma over a substrate to be maintained in a desired state easily.

To attain the above object, according to a first aspect of the invention, there is provided a substrate processing apparatus for carrying out etching as plasma processing on a substrate, comprising a processing chamber in which the substrate is housed, a stage that is disposed in the processing chamber and on which the substrate is mounted, and at least one processing gas introducing unit that introduces a processing gas into the processing chamber, wherein the processing gas introducing unit is a projecting body that projects out into the processing chamber, and has therein a plurality of processing gas introducing holes that open out in different directions to one another.

According to the first aspect of the invention, the processing gas introducing unit is a projecting body that projects out into the processing chamber, and has therein a plurality of processing gas introducing holes that open out in different directions to one another. The processing gas can thus be jetted out from a single point into the processing chamber. Consequently, diffusion of the processing gas over the substrate mounted on the stage can be prevented, and hence the flow line distribution of the processing gas over the substrate can be controlled easily. As a result, the state of the plasma over the substrate can be maintained in a desired state easily. Moreover, due to the above, the uniformity of the etch rate of the substrate, and the controllability of the shape of grooves formed through etching can be improved.

Preferably, the processing gas introducing holes are divided into at least two processing gas introducing hole groups, and a flow rate of the processing gas introduced into the processing chamber is controlled independently for each of the processing gas introducing hole groups.

According to the first aspect of the invention, the flow rate of the processing gas introduced into the processing chamber is controlled independently for each of the processing gas introducing hole groups. Consequently, the flow line distribution of the processing gas over the substrate can be controlled precisely. As a result, the state of the plasma over the substrate can be maintained in a desired state reliably.

Preferably, the processing gas introducing unit has a tip that is a hemispherical projecting body.

According to the first aspect of the invention, the tip of the processing gas introducing unit is a hemispherical projecting body. As a result, the processing gas introducing holes can be made to open out uniformly in all directions into the processing chamber, and hence the flow line distribution of the processing gas over the substrate can be controlled more easily.

More preferably, the processing gas introducing holes are divided into a first processing gas introducing hole group and a second processing gas introducing hole group, the first processing gas introducing hole group comprises ones of the processing gas introducing holes that open out within a region surrounded by a line of intersection where a cone that has its apex as a center of the hemisphere and broadens out toward the stage intersects with a surface of the hemisphere, and the second processing gas introducing hole group comprises ones of the processing gas introducing holes that are not included in the first processing gas introducing hole group.

According to the first aspect of the invention, the first processing gas introducing hole group comprises ones of the processing gas introducing holes that open out within a region surrounded by a line of intersection where a cone that has its apex as the center of the hemisphere and broadens out toward the stage intersects with the surface of the hemisphere, and the second processing gas introducing hole group comprises ones of the processing gas introducing holes that are not included in the first processing gas introducing hole group. As a result, the processing gas introducing holes in each of the processing gas introducing hole groups are disposed symmetrically with respect to a central axis of the hemisphere, and hence the flow rate of the processing gas jetted out in all directions can be made uniform for each of the processing gas introducing hole groups, and thus the flow line distribution of the processing gas over the substrate can be controlled more easily.

Still preferably, the cone has an apex angle in a range of 120°±2°.

According to the first aspect of the invention, the cone dividing the first processing gas introducing hole group from the second processing gas introducing hole group has an apex angle in a range of 120°±2°. The number of the processing gas introducing holes contained in the first processing gas introducing hole group, and the number of the processing gas introducing holes contained in the second processing gas introducing hole group can thus be made to be substantially equal. Consequently, in the case of changing the flow rate of the processing gas introduced in from each of the processing gas introducing hole groups, the change in the flow rate of the processing gas jetted out from the processing gas introducing holes in the first processing gas introducing hole group, and the change in the flow rate of the processing gas jetted out from the processing gas introducing holes in the second processing gas introducing hole group can be made substantially equal. As a result, the flow line distribution of the processing gas over the substrate can be controlled easily and reliably.

More preferably, the processing gas introducing unit has an outer structure including a surface of the hemisphere, and an inner structure enclosed by the outer structure.

According to the first aspect of the invention, the processing gas introducing unit has an outer structure including the surface of the hemisphere, and an inner structure enclosed by the outer structure. As a result, buffer chambers for the processing gas can be formed easily by providing a space between the outer structure and the inner structure, and hence the processing gas introducing unit can be manufactured easily.

Preferably, the substrate has a polysilicon layer, and the etching etches the polysilicon layer.

According to the first aspect of the invention, the etching etches the polysilicon layer on the substrate. In the substrate processing apparatus that etches a polysilicon layer, a space above the substrate mounted on the stage is defined relatively large. Because the substrate processing apparatus allows the flow line distribution of the processing gas on the substrate to be easily controlled even when a space above the substrate is defined relatively large, the state of plasma over the substrate can be easily maintained in a desired state to properly etch the polysilicon layer.

To attain the above object, according to a second aspect of the invention, there is provided a substrate processing method implemented by a substrate processing apparatus for carrying out etching as plasma processing on a substrate, including a processing chamber in which the substrate is housed, and at least one processing gas introducing unit that introduces a processing gas into the processing chamber, wherein the processing gas introducing unit is a projecting body that projects out into the processing chamber, and has therein a plurality of processing gas introducing holes that open out in different directions to one another, the processing gas introducing holes being divided into at least two processing gas introducing hole groups, the substrate processing method comprising: independently controlling a flow rate of the processing gas introduced into the processing chamber by each of the processing gas introducing hole groups.

According to the second aspect of the invention, the flow rate of the processing gas introduced into the processing chamber is controlled independently for each of the processing gas introducing hole groups. Consequently, the flow line distribution of the processing gas over the substrate can be controlled precisely. As a result, the state of the plasma over the substrate can be maintained in a desired state easily. Moreover, due to the above, the uniformity of the etch rate of the substrate can be improved, and moreover the change in a CD (critical dimension) value due to the etching can be controlled.

The above and other objects, features, and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus according to an embodiment of the present invention.

FIG. 2 is a sectional view schematically showing the construction of a processing gas introducing nozzle appearing in FIG. 1.

FIGS. 3A and 3B are drawings relating to an etch rate distribution measurement experiment in Example 1 of the present invention; FIG. 3A is a view for explaining the etch rate distribution measurement experimental method in Example 1; and FIG. 3B is a graph showing the etch rate distribution measurement results in Example 1.

FIGS. 4A and 4B are drawings relating to an etch rate distribution measurement experiment in Comparative Example 1 of the present invention; FIG. 4A is a view for explaining the etch rate distribution measurement experimental method in Comparative Example 1; and FIG. 4B is a graph showing the etch rate distribution measurement results in Comparative Example 1.

FIGS. 5A and 5B are drawings relating to an etch rate distribution measurement experiment in Comparative Example 2 of the present invention; FIG. 5A is a view for explaining the etch rate distribution measurement experimental method in Comparative Example 2; and FIG. 5B is a graph showing the etch rate distribution measurement results in Comparative Example 2.

FIGS. 6A to 6D are diagrams showing results of simulating a flow line distribution in a processing space in Example 2 of the present invention; FIG. 6A is a diagram showing the results in the case that the ratio between a flow rate of a processing gas introduced from a central portion processing gas introducing hole group and a flow rate of the processing gas introduced from a peripheral portion processing gas introducing hole group was set to 0:100; FIG. 6B is a diagram showing the results in the case that the above ratio was set to 25:75; FIG. 6C is a diagram showing the results in the case that the above ratio was set to 50:50; and FIG. 6D is a diagram showing the results in the case that the above ratio was set to 75:25.

FIGS. 7A to 7C are diagrams showing results of simulating the flow line distribution in the processing space in Comparative Example 3 of the present invention; FIG. 7A is a diagram showing the results in the case that the ratio between the flow rate of the processing gas introduced from the central portion processing gas introducing hole group and the flow rate of the processing gas introduced from the peripheral portion processing gas introducing hole group was set to 0:100; FIG. 7B is a diagram showing the results in the case that the above ratio was set to 25:75; and FIG. 7C is a diagram showing the results in the case that the above ratio was set to 50:50.

FIGS. 8A and 8B are diagrams showing results of simulating the flow line distribution in the processing space in Comparative Example 4 of the present invention; FIG. 8A is a diagram showing the results in the case that the ratio between the flow rate of the processing gas introduced from the central portion processing gas introducing hole group and the flow rate of the processing gas introduced from the peripheral portion processing gas introducing hole group was set to 0:100; and FIG. 8B is a diagram showing the results in the case that the above ratio was set to 25:75.

FIGS. 9A and 9B are views showing film structures of a wafer in Examples 3 to 7 and Comparative Examples 5 and 6 of the present invention; FIG. 9A is a view showing a state before etching; and FIG. 9B is a view showing a state after the etching.

FIG. 10 is a graph showing the distribution of a CD value shift in Example 3 of the present invention.

FIG. 11 is a graph showing the distribution of the CD value shift in Example 4 of the present invention.

FIG. 12 is a graph showing the distribution of the CD value shift in Example 5 of the present invention.

FIG. 13 is a graph showing the distribution of the CD value shift in Examples 6 and 7 of the present invention.

FIG. 14 is a graph showing the distribution of the CD value shift in Comparative Examples 5 and 6 of the present invention.

### DESCRIPTION OF THE PREFERRED EMBODIMENTS

The present invention will now be described with reference to the drawings showing embodiments thereof.

First, a substrate processing apparatus according to an embodiment of the present invention will be described.

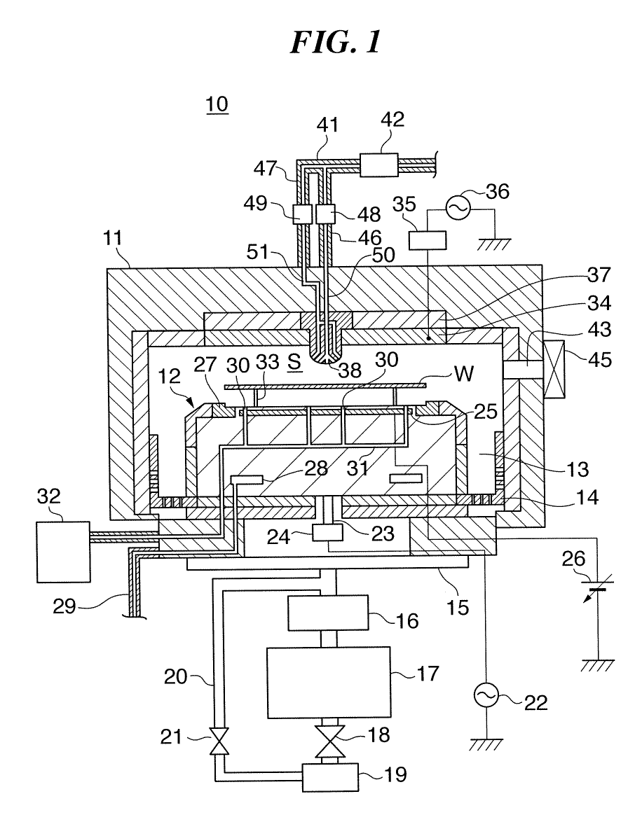

FIG. 1 is a sectional view schematically showing the construction of a substrate processing apparatus according to an embodiment of the present invention. A plasma processing apparatus constituting the substrate processing apparatus is constructed so as to carry out plasma processing such as etching particularly on polysilicon layers on semiconductor wafers W (hereinafter referred to merely as “wafers W”) as substrates.

As shown in FIG. 1, the plasma processing apparatus 10 has a cylindrical chamber 11 made of aluminum having an inner wall thereof coated with alumite. A cylindrical stage 12 is disposed in the chamber 11 on which is mounted a wafer W having a diameter of, for example, 300 mm.

In the plasma processing apparatus 10, an exhaust path 13 that acts as a flow path through which gas molecules above the stage 12 are exhausted to the outside of the chamber 11 is formed between an inner side wall of the chamber 11 and a side surface of the stage 12. An annular baffle plate 14 that prevents leakage of plasma is disposed part way along the exhaust path 13. A space in the exhaust path 13 downstream of the baffle plate 14 bends round below the stage 12, and is communicated with an adaptive pressure control valve (APC valve) 15, which is a variable butterfly valve. The APC valve 15 is connected via an isolator valve 16 to a turbo-molecular pump (TMP) 17, which is an exhausting pump for evacuation. The TMP 17 is connected via a valve 18 to a dry pump (DP) 19, which is also an exhausting pump. The exhaust system (main exhaust line) comprised of the APC valve 15, the isolator valve 16, the TMP 17, the valve 18, and the DP 19 is used for controlling the pressure in the chamber 11 using the APC valve 15, and also for reducing the pressure in the chamber 11 down to a substantially vacuum state using the TMP 17 and the DP 19.

Moreover, piping 20 is connected from between the APC valve 15 and the isolator valve 16 to the DP 19 via a valve 21. An exhaust system (bypass line) comprised of the piping 20 and the valve 21 bypasses the TMP 17, and is used for roughing the chamber 11 using the DP 19.

A lower electrode radio frequency power source 22 is connected to the stage 12 via a feeder rod 23 and a matcher 24. The lower electrode radio frequency power source 22 supplies predetermined radio frequency electrical power to the stage 12. The stage 12 thus acts as a lower electrode. The matcher 24 reduces reflection of the radio frequency electrical power from the stage 12 so as to maximize the efficiency of the supply of the radio frequency electrical power into the stage 12.

A disk-shaped ESC electrode plate 25 comprised of an electrically conductive film is provided in an upper portion of the stage 12. A DC power source 26 is electrically connected to the ESC electrode plate 25. A wafer W is attracted to and held on an upper surface of the stage 12 through a Johnsen-Rahbek force or a Coulomb force generated by a DC voltage applied to the ESC electrode plate 25 from the DC power source 26. Moreover, an annular focus ring 27 is provided on an upper side of the stage 12 so as to surround the wafer W attracted to and held on the upper surface of the stage 12. The focus ring 27 is made of silicon, SiC (silicon carbide), or Qz (quartz), and is exposed to a processing space S between an upper electrode plate 34, described below, and the stage 12, and focuses the plasma in the processing space S toward a surface of the wafer W, thus improving the efficiency of the plasma processing.

An annular coolant chamber 28 that extends, for example, in a circumferential direction is provided inside the stage 12. A coolant, for example cooling water or a Galden (registered trademark) fluid, at a predetermined temperature is circulated through the coolant chamber 28 via coolant piping 29 from a chiller unit (not shown). A temperature of the stage 12, and hence of the wafer W attracted to and held on the upper surface of the stage 12, is controlled through the temperature of the coolant.

A plurality of heat-transmitting gas supply holes 30 that face the wafer W are provided in a portion of the upper surface of the stage 12 on which the wafer W is attracted and held (hereinafter referred to as the “attracting surface”). The heat-transmitting gas supply holes 30 are connected to a heat-transmitting gas supply unit 32 via a heat-transmitting gas supply line 31 provided inside the stage 12. The heat-transmitting gas supply unit 32 supplies helium (He) gas as a heat-transmitting gas via the heat-transmitting gas supply holes 30 into a gap between the attracting surface and a backside surface of the wafer W. The heat-transmitting gas supply holes 30, the heat-transmitting gas supply line 31, and the heat-transmitting gas supply unit 32 together constitute a heat-transmitting gas supply apparatus. Note that the type of the backside gas is not limited to being helium, but rather may instead be an inert gas such as nitrogen (N₂), argon (Ar), krypton (Kr), or xenon (Xe), or oxygen (O₂) or the like.

Three pusher pins 33 are provided in the attracting surface of the stage 12 as lifting pins that can be made to project out from the upper surface of the stage 12. The pusher pins 33 are connected to a motor (not shown) by a ball screw (not shown), and can be made to project out from the attracting surface through rotational motion of the motor, which is converted into linear motion by the ball screw. The pusher pins 33 are housed inside the stage 12 when a wafer W is being attracted to and held on the attracting surface so that the wafer W can be subjected to the plasma processing, and are made to project out from the upper surface of the stage 12 so as to lift the wafer W up away from the stage 12 when the wafer W is to be transferred out from the chamber 11 after having been subjected to the plasma processing.

The upper electrode plate 34, which is disk-shaped, is disposed in a ceiling portion of the chamber 11 facing the stage 12. An upper electrode radio frequency power source 36 is connected to the upper electrode plate 34 via a matcher 35. The upper electrode radio frequency power source 36 supplies predetermined radio frequency electrical power to the upper electrode plate 34. The matcher 35 has a similar function to the matcher 24, described earlier. A cooling plate 37 is disposed on an upper side of the upper electrode plate 34. The cooling plate 37 cools the upper electrode plate 34, which is heated during the plasma processing. Because the plasma processing apparatus 10 etches the polysilicon layer on the wafer W, the space (gap) between the upper electrode plate 34 and the stage 12 is defined relatively large so that the processing space S is defined relatively large.

A processing gas introducing nozzle 38 (processing gas introducing unit) that penetrates through the upper electrode plate 34 and the cooling plate 37 and for which a tip thereof that projects out into the processing space S is a dome-shaped (hemispherical) projecting body is disposed in the ceiling portion of the chamber 11. The tip of the processing gas introducing nozzle 38 projects out from the upper electrode plate 34 toward a center of the wafer W mounted on the stage 12.

A processing gas supply unit (not shown) for supplying a processing gas into the chamber 11 is disposed outside the chamber 11. The processing gas supply unit is connected to a processing gas supply pipe 41. The processing gas supply pipe 41 branches part way therealong into two processing gas introducing pipes 46 and 47. The processing gas introducing pipes 46 and 47 have respectively therein processing gas valves 48 and 49 for which an opening/closing amount can be adjusted. The opening/closing amounts of the processing gas valves 48 and 49 are controlled independently of one another by a control unit (not shown) of the plasma processing apparatus 10.

The processing gas introducing pipes 46 and 47 are connected respectively to processing gas introducing lines 50 and 51 provided in the ceiling portion of the chamber 11. Each of the processing gas introducing lines 50 and 51 is connected to the processing gas introducing nozzle 38. Here, the processing gas introducing pipe 46, the processing gas valve 48, and the processing gas introducing line 50 constitute a central portion processing gas introducing system, and the processing gas introducing pipe 47, the processing gas valve 49, and the processing gas introducing line 51 constitute a peripheral portion processing gas introducing system. For each of the central portion processing gas introducing system and the peripheral portion processing gas introducing system, a flow rate of the processing gas supplied into the processing gas introducing nozzle 38 can be adjusted using the processing gas valve 48 or 49 respectively. The processing gas introducing nozzle 38 into which the processing gas is supplied by the central portion processing gas introducing system and the peripheral portion processing gas introducing system supplies the processing gas into the processing space S.

A piping insulator 42 is disposed part way along the processing gas supply pipe 41. The piping insulator 42 is made of an electrically insulating material, and prevents the radio frequency electrical power supplied to the upper electrode plate 34 from leaking into the processing gas supply unit via the processing gas supply pipe 41 and the like.

A transfer port 43 for the wafers W is provided in a side wall of the chamber 11 in a position at the height of a wafer W that has been lifted up from the stage 12 by the pusher pins 33. A gate valve 45 for opening and closing the transfer port 43 is provided in the transfer port 43.

When subjecting a wafer W to the plasma processing in the plasma processing apparatus 10, first, the gate valve 45 is opened, and the wafer W to be processed is transferred into the chamber 11, and attracted to and held on the attracting surface of the stage 12 by applying a DC voltage to the ESC electrode plate 25. Moreover, the processing gas (e.g. a mixed gas comprised of CF₄ gas, O₂ gas, and Ar gas) is supplied from the processing gas introducing nozzle 38 into the chamber 11, and the pressure inside the chamber 11 is controlled to a predetermined value using the APC valve 15 and so on. Furthermore, radio frequency electrical power is applied into the processing space S in the chamber 11 from the stage 12 and the upper electrode plate 34. The processing gas introduced in from the processing gas introducing nozzle 38 is thus turned into plasma in the processing space S. The plasma is focused onto the surface of the wafer W by the focus ring 27, whereby the surface of the wafer W is subjected to the plasma processing.

Operation of the component elements of the plasma processing apparatus 10 described above is controlled in accordance with a program for the plasma processing by a control unit such as a computer (not shown).

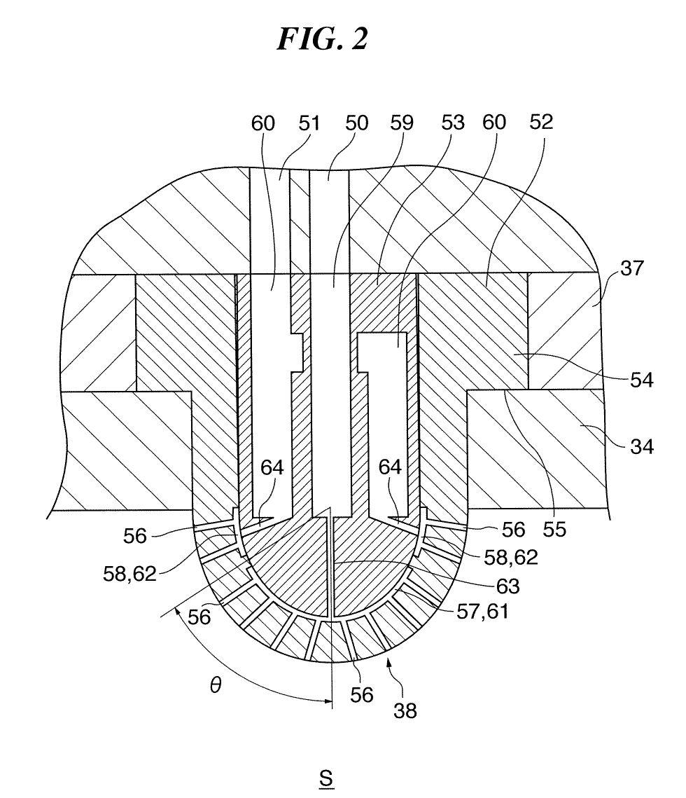

FIG. 2 is a sectional view schematically showing the construction of the processing gas introducing nozzle appearing in FIG. 1.

As shown in FIG. 2, the processing gas introducing nozzle 38 is comprised of a cylindrical outer structural portion 52 (outer structure), and a cylindrical inner structural portion 53 (inner structure) enclosed by the outer structural portion 52. A tip of the outer structural portion 52 has a hemispherical shape on each of an outside and an inside thereof, and a tip of the inner structural portion 53 has a hemispherical shape corresponding to the shape of the inside of the tip of the outer structural portion 52.

The outer structural portion 52 has a flange portion 54, the flange portion 54 contacting a stepped portion 55 formed by the cooling plate 37 and the upper electrode plate 34, whereby the amount by which the processing gas introducing nozzle 38 projects out into the processing space S is controlled. Specifically, only the hemisphere of the tip of the outer structural portion 52 projects out into the processing space S. Moreover, the outer structural portion 52 has in the hemisphere of the tip thereof a plurality of cylindrical hole-shaped processing gas introducing holes 56 that penetrate through the outer structural portion 52 from the inside to the outside thereof. The processing gas introducing holes 56 are disposed such as to radiate out from a center of the hemisphere of the tip of the outer structural portion 52. The processing gas introducing holes 56 thus open out at an outer surface of the hemisphere of the outer structural portion 52 uniformly in all directions into the processing space S.

Moreover, in an inner surface of the outer structural portion 52, a central portion recessed portion 57 is formed over substantially the whole of the interior of a region surrounded by a line of intersection where the inner surface of the outer structural portion 52 intersects with a cone that has its apex as the center of the hemisphere of the inner surface, broadens out toward the wafer W mounted on the stage 12, and has an apex angle of 120° (i.e. the angle θ shown in FIG. 2 is 60°). Furthermore, a substantially annular peripheral portion recessed portion 58 is formed in the inner surface of the outer structural portion 52 outside the above region such as to surround the central portion recessed portion 57. Each of the processing gas introducing holes 56 communicates with one of the central portion recessed portion 57 and the peripheral portion recessed portion 58. The processing gas introducing holes 56 are thus divided into a central portion processing gas introducing hole group (first processing gas introducing hole group) communicating with the central portion recessed portion 57, and a peripheral portion processing gas introducing hole group (second processing gas introducing hole group) communicating with the peripheral portion recessed portion 58. That is, the central portion processing gas introducing hole group is comprised of the processing gas introducing holes 56 that open out within the region of the outer surface of the hemisphere of the tip of the outer structural portion 52 surrounded by the line of intersection where the outer surface intersects with the cone that has its apex as the center of the hemisphere and broadens out toward the wafer W, and the peripheral portion processing gas introducing hole group is comprised of, out of the processing gas introducing holes 56 that open out at the outer surface of the hemisphere of the outer structural portion 52, those processing gas introducing holes 56 not included in the central portion processing gas introducing hole group.

Here, a surface area S_{CNT} of the outer surface of the hemisphere of the tip of the outer structural portion 52 where the processing gas introducing holes 56 of the central portion processing gas introducing hole group open out is given by formula (1) below.
S_{CNT}=2πr²(1−cos θ) (1)
In the present embodiment, θ is 60°, and hence the surface area S_{CNT} is equal to the surface area S_{EDG} of the outer surface of the hemisphere of the tip of the outer structural portion 52 where the processing gas introducing holes 56 of the peripheral portion processing gas introducing hole group open out. Moreover, the pitch between a pair of adjacent ones of the processing gas introducing holes 56 is the same for all such pairs, regardless of whether the processing gas introducing holes 56 are in the central portion processing gas introducing hole group or the peripheral portion processing gas introducing hole group. The number of the processing gas introducing holes 56 contained in the central portion processing gas introducing hole group is thus equal to the number of the processing gas introducing holes 56 contained in the peripheral portion processing gas introducing hole group.

The inner structural portion 53 has therein a central portion processing gas introducing path 59 provided along a central axis of the inner structural portion 53, and a peripheral portion processing gas introducing path 60 provided such as to surround the central portion processing gas introducing path 59. The central portion processing gas introducing path 59 and the peripheral portion processing gas introducing path 60 are connected to the processing gas introducing lines 50 and 51 respectively.

When the inner structural portion 53 has been inserted into the outer structural portion 52, the tip of the inner structural portion 53 and the central portion recessed portion 57 together form a central portion buffer chamber 61, and the tip of the inner structural portion 53 and the peripheral portion recessed portion 58 together form a peripheral portion buffer chamber 62.

Moreover, the inner structural portion 53 has therein a communicating path 63 that communicates the central portion buffer chamber 61 and the central portion processing gas introducing path 59 together, and a communicating path 64 that communicates the peripheral portion buffer chamber 62 and the peripheral portion processing gas introducing path 60 together. The processing gas introducing holes 56 contained in the central portion processing gas introducing hole group are thus communicated with the central portion processing gas introducing system via the central portion buffer chamber 61, the communicating path 63, and the central portion processing gas introducing path 59, and the processing gas introducing holes 56 contained in the peripheral portion processing gas introducing hole group are communicated with the peripheral portion processing gas introducing system via the peripheral portion buffer chamber 62, the communicating path 64, and the peripheral portion processing gas introducing path 60.

As described above, the flow rate of the processing gas supplied in can be adjusted for each of the central portion processing gas introducing system and the peripheral portion processing gas introducing system, and hence the flow rates of the processing gas introduced into the processing space S by the central portion processing gas introducing hole group and the peripheral portion processing gas introducing hole group can be controlled independently of one another.

In the processing gas introducing nozzle 38, each of the outer structural portion 52 and the inner structural portion 53 is made of quartz.

According to the plasma processing apparatus 10 described above, the processing gas introducing nozzle 38 is a hemispherical projecting body that projects out into the processing space S toward the center of the wafer W, the surface of the hemisphere having therein the plurality of processing gas introducing holes 56 that open out uniformly in all directions into the processing space S. The processing gas can thus be jetted out from a single point into the processing space S. As a result, diffusion of the processing gas over the wafer W can be prevented. Moreover, the opening directions of the plurality of processing gas introducing holes 56 are given directionality (each of the opening directions is set to be a desired direction), whereby the flow line distribution of the processing gas over the wafer W can be controlled easily. As a result, the state of the plasma over the wafer W can be maintained in a desired state easily. Moreover, due to the above, the uniformity of the etch rate of the wafer W, the controllability of the shape of grooves formed through etching, and the controllability of the CD value can be improved.

In the plasma processing apparatus 10, although the processing space S is defined relatively large, the flow line distribution of the processing gas on the wafer W can be easily controlled. Therefore, the state of the plasma over the wafer W can be easily maintained in a desired state to properly etch the polysilicon layer on the wafer W.

For the processing gas introducing nozzle 38 described above, the flow rates of the processing gas introduced into the processing space S by the central portion processing gas introducing hole group and the peripheral portion processing gas introducing hole group can be controlled independently of one another. As a result, the flow line distribution of the processing gas over the wafer W can be controlled precisely.

Moreover, the tip of the processing gas introducing nozzle 38 is a hemispherical projecting body, and the processing gas introducing holes 56 are disposed such as to radiate out from the center of the hemisphere. As a result, the processing gas introducing holes 56 can be made to open out at the surface of the hemisphere uniformly in all directions into the processing space S, and hence the flow line distribution of the processing gas over the wafer W can be controlled more easily.

In the processing gas introducing nozzle 38, the central portion processing gas introducing hole group is comprised of the processing gas introducing holes 56 that communicate with the central portion recessed portion 57 formed over substantially the whole of the interior of the region surrounded by the line of intersection where the inner surface of the outer structural portion 52 intersects with the cone that has its apex as the center of the hemisphere of the tip of the outer structural portion 52, broadens out toward the wafer W, and has an apex angle of 120°, and the peripheral portion processing gas introducing hole group is comprised of the processing gas introducing holes 56 that communicate with the substantially annular peripheral portion recessed portion 58 formed such as to surround the central portion recessed portion 57. As a result, the processing gas introducing holes 56 in the central portion processing gas introducing hole group and the peripheral portion processing gas introducing hole group are disposed symmetrically with respect to the central axis of the above hemisphere, and hence the flow rate of the processing gas jetted out in all directions can be made uniform for each of the central portion processing gas introducing hole group and the peripheral portion processing gas introducing hole group, and thus the flow line distribution of the processing gas over the wafer W can be controlled more easily.

Moreover, for the processing gas introducing nozzle 38, the apex angle of the cone dividing the central portion processing gas introducing hole group from the peripheral portion processing gas introducing hole group is 120°. As a result, the number of the processing gas introducing holes 56 contained in the central portion processing gas introducing hole group, and the number of the processing gas introducing holes 56 contained in the peripheral portion processing gas introducing hole group can be made substantially equal. In the case of changing the flow rate of the processing gas introduced in from the central portion processing gas introducing hole group and the peripheral portion processing gas introducing hole group, the change in the flow rate of the processing gas jetted out from the processing gas introducing holes 56 in the central portion processing gas introducing hole group, and the change in the flow rate of the processing gas jetted out from the processing gas introducing holes 56 in the peripheral portion processing gas introducing hole group can thus be made substantially equal. As a result, the flow line distribution of the processing gas over the wafer W can be controlled easily and reliably.

Moreover, because the processing gas introducing nozzle 38 is comprised of the outer structural portion 52, and the inner structural portion 53 enclosed by the outer structural portion 52, by providing a space between the outer structural portion 52 and the inner structural portion 53, the buffer chambers 61 and 62 for the processing gas can be formed easily, and hence the processing gas introducing nozzle 38 can be manufactured easily. Furthermore, because the processing gas introducing nozzle 38 has such a divided structure, there is no need to form unnecessary space therein for forming processing gas channels and buffer chambers. As a result, an abnormal electrical discharge due to plasma infiltrating into the processing gas introducing nozzle 38 can be prevented from occurring. Note also that from the viewpoint of preventing an abnormal electrical discharge from occurring, it is preferable to make the structure of each of the processing gas introducing holes 56 be a labyrinth shape rather than a cylindrical hole shape.

For the processing gas introducing nozzle 38 described above, because the processing gas is jetted out from a single point into the processing space S, the area of contact between the processing gas and internal structure of the processing gas introducing unit can be reduced compared with a conventional shower head, and hence production of reaction product through chemical reaction between the processing gas and a constituent material of the internal structure can be suppressed. Moreover, because the outer structural portion 52 and the inner structural portion 53 of the processing gas introducing nozzle 38 are made of quartz which does not react with a CF type gas constituting the processing gas and not aluminum which readily reacts with such a CF type gas, production of reaction product can be prevented. As a result, reaction product can be prevented from breaking away from the internal structure and infiltrating into the processing space S to form particles, and hence the yield of semiconductor devices manufactured from the wafers W can be improved. Note that the material constituting the outer structural portion 52 and the inner structural portion 53 is not limited to quartz, but rather may be another material that does not react with a CF type gas, for example a ceramic or silicon.

Moreover, in the plasma processing apparatus 10, by using the processing gas introducing nozzle 38 instead of a conventional shower head, the need to provide processing gas introducing holes in the upper electrode plate is eliminated, and hence the structure of the upper electrode plate can be simplified, whereby the cost of the plasma processing apparatus 10 can be reduced.

In the plasma processing apparatus 10 described above, the processing gas introducing nozzle 38 is a hemispherical projecting body; however, the shape of the processing gas introducing nozzle 38 is not limited thereto, but rather the shape may instead be, for example, a cylinder or a cone that projects out into the processing space S.

Moreover, the plasma processing apparatus 10 has one processing gas introducing nozzle 38; however, the number of processing gas introducing nozzles 38 in the plasma processing apparatus 10 is not limited thereto, but rather may instead be, for example, 2 or more. Moreover, the location in which the processing gas introducing nozzle 38 is disposed is not limited to a position facing the center of the wafer W, but rather the processing gas introducing nozzle 38 may instead be disposed such as to face, for example, a peripheral portion of the wafer W.

The processing gas used in the plasma processing apparatus 10 described above may be, for example, a mixed gas obtained by adding O₂ gas and an inert gas such as He to a gas containing a combination of CH₂F₂, CH₃F, CHF₃, C₄F₈, and so on, or a mixed gas obtained by adding O₂ gas and an inert gas such as He to a brominated gas or a chlorinated gas.

In the plasma processing apparatus 10 described above, the substrates subjected to the plasma processing are semiconductor wafers; however, the substrates subjected to the plasma processing are not limited thereto, but rather may instead be, for example, LCD (liquid crystal display) or FPD (flat panel display) glass substrates or the like.

### EXAMPLES

Next, examples of the present invention will be described in detail.

### Example 1

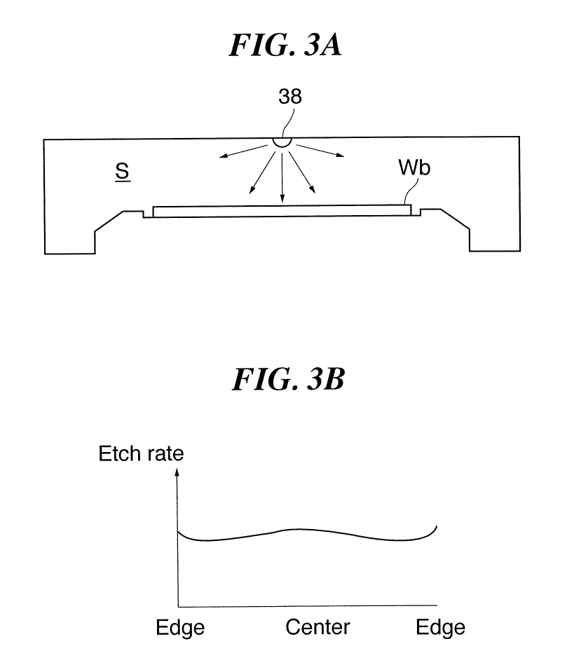

First, as a wafer to be subjected to etching, a polysilicon film blanket wafer Wb (a wafer having a polysilicon film on a surface thereof formed like a blanket) was prepared. Next, as shown in FIG. 3A, the prepared blanket wafer Wb was transferred into the chamber 11 of the plasma processing apparatus 10, and a mixed gas obtained by adding O₂ gas and an inert gas such as He to a brominated gas or a chlorinated gas was supplied as a processing gas into the processing space S in the chamber 11 from the processing gas introducing nozzle 38 in all directions into the processing space S. At this time, the flow rate of the processing gas jetted out into the processing space S by the central portion processing gas introducing hole group, and the flow rate of the processing gas jetted out into the processing space S by the peripheral portion processing gas introducing hole group were equal. Next, radio frequency electrical power was applied into the processing space S so as to produce plasma from the supplied processing gas, whereby the blanket wafer Wb was etched.

After that, the etched blanket wafer Wb was transferred out from the chamber 11, and the distribution of the etch rate over the surface of the blanket wafer Wb was measured; the measured etch rate distribution is shown as a graph in FIG. 3B.

### Comparative Example 1

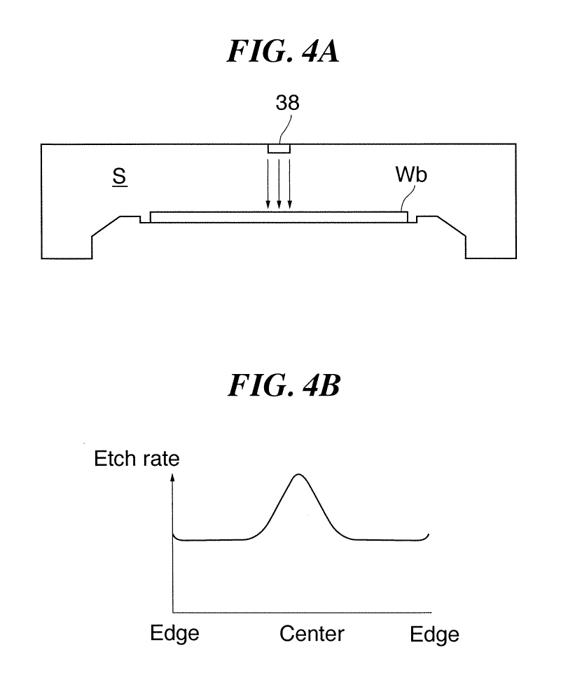

First, as in Example 1, a polysilicon film blanket wafer Wb was prepared. Next, as shown in FIG. 4A, the blanket wafer Wb was transferred into a chamber of a substrate processing apparatus having a processing gas introducing nozzle 65 that jets the processing gas in a single direction toward the stage, and the same processing gas as in Example 1 was jetted into the processing space S in the chamber from the processing gas introducing nozzle 65 concentratedly toward the center of the blanket wafer Wb. Next, radio frequency electrical power was applied into the processing space S so as to produce plasma from the supplied processing gas, whereby the blanket wafer Wb was etched.

After that, the etched blanket wafer Wb was transferred out from the chamber, and the distribution of the etch rate over the surface of the blanket wafer Wb was measured; the measured etch rate distribution is shown as a graph in FIG. 4B.

### Comparative Example 2

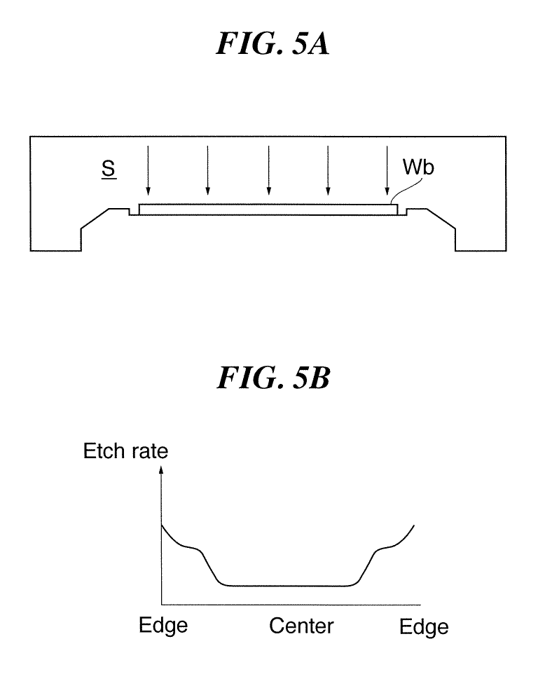

First, as in Example 1, a polysilicon film blanket wafer Wb was prepared. Next, as shown in FIG. 5A, the blanket wafer Wb was transferred into a chamber of a substrate processing apparatus having a conventional shower head, and the same processing gas as in Example 1 was jetted into the processing space S in the chamber from the shower head over the whole surface of the blanket wafer Wb. Next, radio frequency electrical power was applied into the processing space S so as to produce plasma from the supplied processing gas, whereby the blanket wafer Wb was etched.

After that, the etched blanket wafer Wb was transferred out from the chamber, and the distribution of the etch rate over the surface of the blanket wafer Wb was measured; the measured etch rate distribution is shown as a graph in FIG. 5B.

From the graphs in FIGS. 3B, 4B, and 5B, it was found that in the case that the processing gas was jetted out concentratedly toward the center of the blanket wafer Wb (Comparative Example 1), the etch rate was high only in a central portion (“Center”) of the blanket wafer Wb, and hence the central portion of the blanket wafer Wb only was etched excessively; moreover, it was found that in the case that the processing gas was jetted out over the whole surface of the blanket wafer Wb (Comparative Example 2), the etch rate in the central portion of the blanket wafer Wb was lower than the etch rate at a peripheral portion (“Edge”), and hence the central portion of the blanket wafer Wb was not readily etched. On the other hand, it was found that in the case that the processing gas was jetted out from a single point in all directions into the processing space S (Example 1), the etch rate was substantially the same at the central portion and the peripheral portion of the blanket wafer Wb, and hence the whole surface of the blanket wafer Wb was etched substantially uniformly.

From the above, it was found that from the viewpoint of improving the uniformity of the etch rate, it is preferable for the processing gas to be jetted out from a single point in all directions into the processing space S.

Next, studies were carried out on the apex angle of the cone dividing the central portion processing gas introducing hole group from the peripheral portion processing gas introducing hole group in the processing gas introducing nozzle 38, by simulating the flow line distribution in the processing space using a computer.

### Example 2

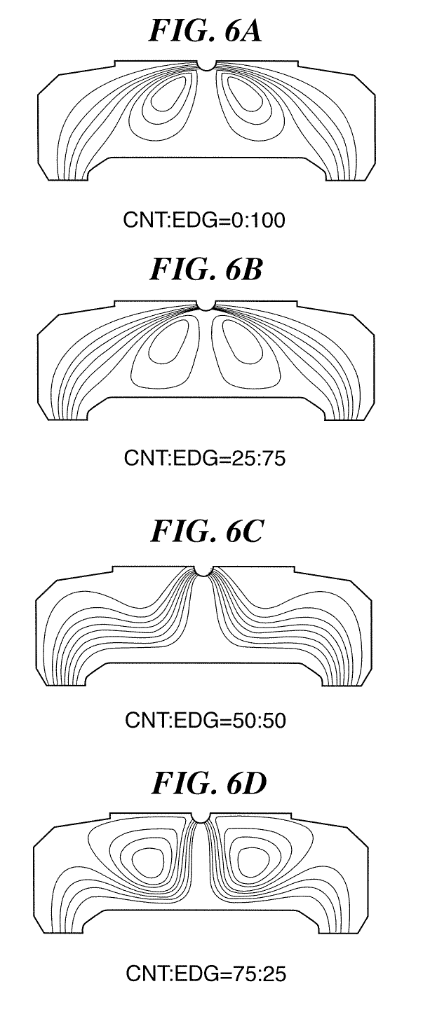

The apex angle of the above cone was set to 120°, the ratio between the flow rate of the processing gas introduced from the central portion processing gas introducing hole group (CNT) and the flow rate of the processing gas introduced from the peripheral portion processing gas introducing hole group (EDG) was set to 0:100, and a simulation of the flow line distribution in the processing space under this condition was carried out. The results of the simulation are shown in FIG. 6A. The flow line distribution is shown using contour lines in FIG. 6A. Moreover, the above ratio was set to each of 25:75, 50:50, and 75:25, and a similar simulation was carried out under each of these conditions; the results are shown respectively in FIGS. 6B, 6C, and 6D.

### Comparative Example 3

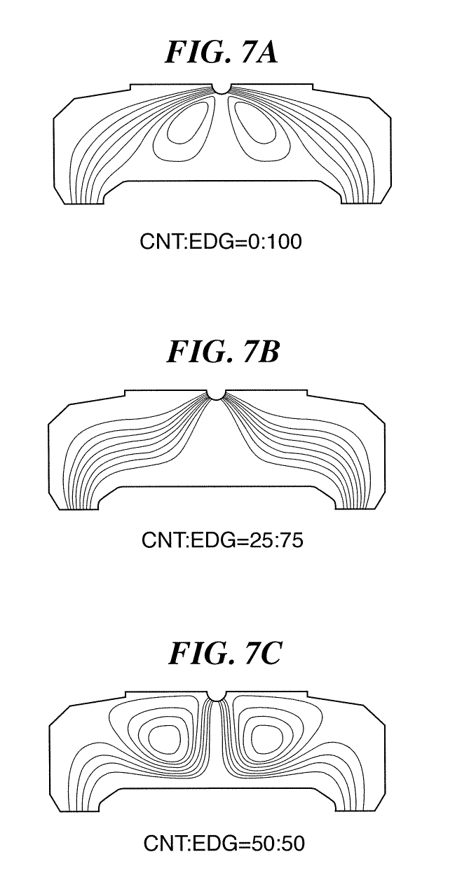

The apex angle of the above cone was set to 90°, the ratio between the flow rate of the processing gas introduced from the central portion processing gas introducing hole group and the flow rate of the processing gas introduced from the peripheral portion processing gas introducing hole group was set to 0:100, and a simulation of the flow line distribution in the processing space under this condition was carried out; the results of the simulation are shown in FIG. 7A. Moreover, the above ratio was set to each of 25:75 and 50:50, and a similar simulation was carried out under each of these conditions; the results are shown respectively in FIGS. 7B and 7C. Note that in the case that the above ratio was set to 75:25, the simulation did not converge, and hence results could not be obtained.

### Comparative Example 4

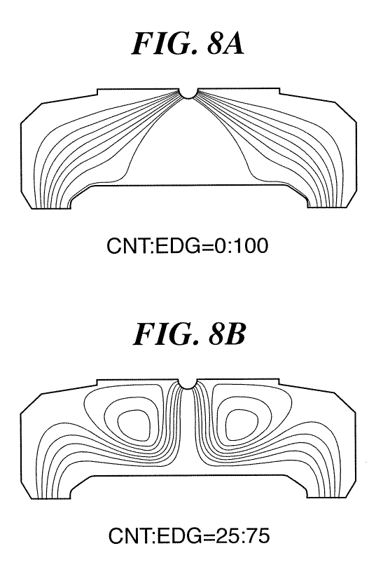

The apex angle of the above cone was set to 60°, the ratio between the flow rate of the processing gas introduced from the central portion processing gas introducing hole group and the flow rate of the processing gas introduced from the peripheral portion processing gas introducing hole group was set to 0:100, and a simulation of the flow line distribution in the processing space under this condition was carried out; the results of the simulation are shown in FIG. 8A. Moreover, the above ratio was set to 25:75, and a similar simulation was carried out under this condition; the results are shown in FIG. 8B. Note that in the case that the above ratio was set to 50:50 or 75:25, the simulation did not converge, and hence results could not be obtained.

Comparing FIGS. 6A to 8B, it was found that the flow line distributions in FIGS. 6D, 7C, and 8B were substantially the same, whereas the flow line distributions in FIGS. 6C, 7B, and 8A were different to one another.

For example, the amount of change in the flow rate of the processing gas introduced from the central portion processing gas introducing hole group and the amount of change in the flow rate of the processing gas introduced from the peripheral portion processing gas introducing hole group upon changing from the state of FIG. 8A to the state of FIG. 8B, these amounts of change upon changing from the state of FIG. 7B to the state of FIG. 7C, and these amounts of change upon changing from the state of FIG. 6C to the state of FIG. 6D are all the same, but the degree of change in the flow line distribution from FIG. 8A to FIG. 8B, the degree of change in the flow line distribution from FIG. 7B to FIG. 7C, and the degree of change in the flow line distribution from FIG. 6C to FIG. 6D are different to one another. Specifically, the degree of change in the flow line distribution from FIG. 8A to FIG. 8B is the greatest, and the degree of change in the flow line distribution from FIG. 6C to FIG. 6D is the smallest.

From the above, it was found that in the case that the apex angle of the above cone is 120°, the degree of change in the flow line distribution with changes in the processing gas flow rates is smallest, the flow line distribution not changing suddenly, and hence this apex angle is optimum for controlling the flow line distribution over the wafer.

Moreover, upon changing the apex angle of the above cone within a range of 118° to 122°, and carrying out simulation of the flow line distribution under the same conditions as in Example 2, similar results to the results shown in FIGS. 6A to 6D were obtained. It was thus found that any apex angle of the cone in a range of 118° to 122° is optimum for controlling the flow line distribution over the wafer.

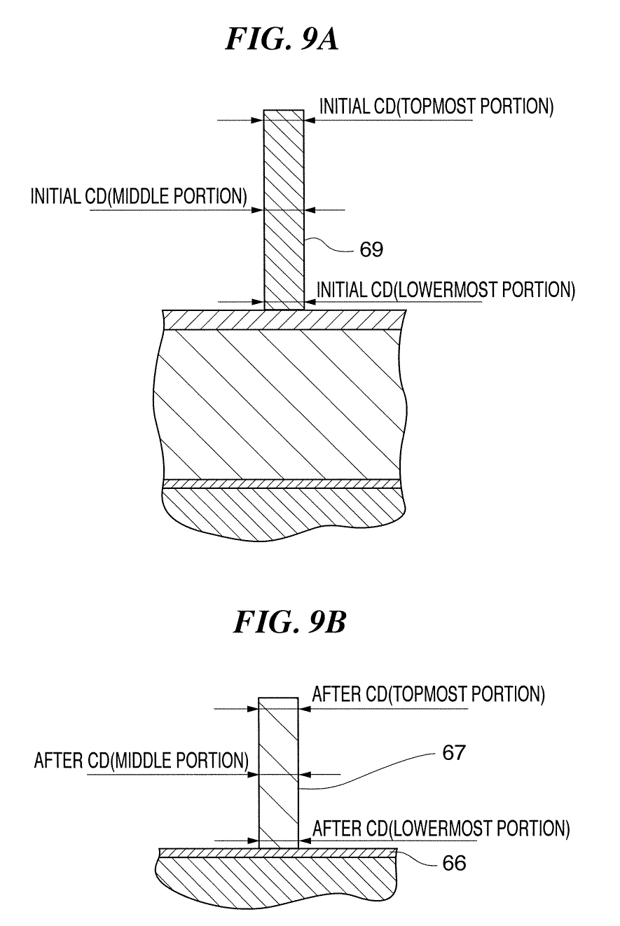

Next, wafer etching results, specifically the shift (amount of change) in a CD value due to the etching, upon changing the processing gas jetting method for the processing gas introducing nozzle 38 was investigated using the plasma processing apparatus 10. Here, as shown in FIG. 9, for a wafer on which are formed in order from the bottom a gate oxide layer 66, a polysilicon layer 67, an ARC layer (anti-reflection layer) 68, and a krypton fluoride resist layer (KrF resist layer) 69, the CD value shift is the difference between the width of the lowermost portion of the krypton fluoride resist layer 69 before etching (FIG. 9A) (“Initial CD”) and the width of the lowermost portion of the polysilicon layer 67 after the etching (FIG. 9B) (“After CD”).

### Example 3

First, the width of the lowermost portion of the krypton fluoride resist layer 69 on a wafer was measured at a plurality of measurement points along two mutually orthogonal diametral directions (an x-direction and a y-direction) on the surface of the wafer.

After that, the wafer was transferred into the chamber 11, a mixed gas comprised of CF₄, CH₂F₂, O₂, and Ar was supplied as a processing gas into the processing space S from the processing gas introducing nozzle 38, and the pressure in the chamber 11 was set to 4.67 Pa (35 mTorr). Moreover, radio frequency electrical powers supplied from the lower electrode radio frequency power source 22 and the upper electrode radio frequency power source 36 were set to 1000 W and 75 W respectively. As a result, plasma was produced, and the ARC layer 68 was etched by the plasma.

Next, a mixed gas comprised of HBr, He, and O₂ was supplied as a processing gas into the processing space S from the processing gas introducing nozzle 38, and the pressure in the chamber 11 was set to 1.33 Pa (10 mTorr). Moreover, the radio frequency electrical powers supplied from the lower electrode radio frequency power source 22 and the upper electrode radio frequency power source 36 were set to 600 W and 100 W respectively. As a result, plasma was produced, and the polysilicon layer 67 was etched by the plasma.

Next, O₂ gas was supplied as a processing gas into the processing space S from the processing gas introducing nozzle 38, and plasma was produced from the O₂ gas, so as to subject the krypton fluoride resist layer 69 and the ARC layer 68 immediately below the krypton fluoride resist layer 69 to ashing by the plasma.

In the present Example, in each of the etching of the ARC layer 68 and the polysilicon layer 67, and the ashing of the krypton fluoride resist layer 69 and so on, the processing gas was jetted into the processing space S from both the central portion processing gas introducing hole group and the peripheral portion processing gas introducing hole group of the processing gas introducing nozzle 38.

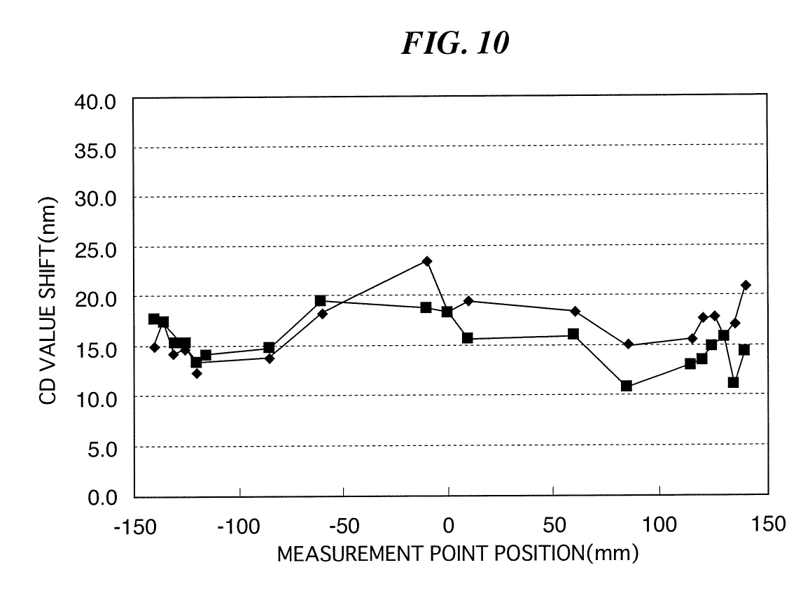

Next, the width of the lowermost portion of the polysilicon layer 67 on the etched wafer was measured at the plurality of measurement points along the two mutually orthogonal diametral directions (the x-direction and the y-direction) on the surface of the wafer. After that, the CD value shift was calculated for each of the measurement points, and plotted on the graph of FIG. 10. Here, “♦” indicates the CD value shifts for the measurement points along the x-direction, and “▪” indicates the CD value shifts for the measurement points along the y-direction.

### Example 4

Etching of the ARC layer 68 and the polysilicon layer 67, and ashing of the krypton fluoride resist layer 69 and so on were carried out as in Example 3. In the present Example, however, in each of the etching of the ARC layer 68 and the polysilicon layer 67, and the ashing of the krypton fluoride resist layer 69 and so on, the processing gas was jetted into the processing space S from only the peripheral portion processing gas introducing hole group of the processing gas introducing nozzle 38.

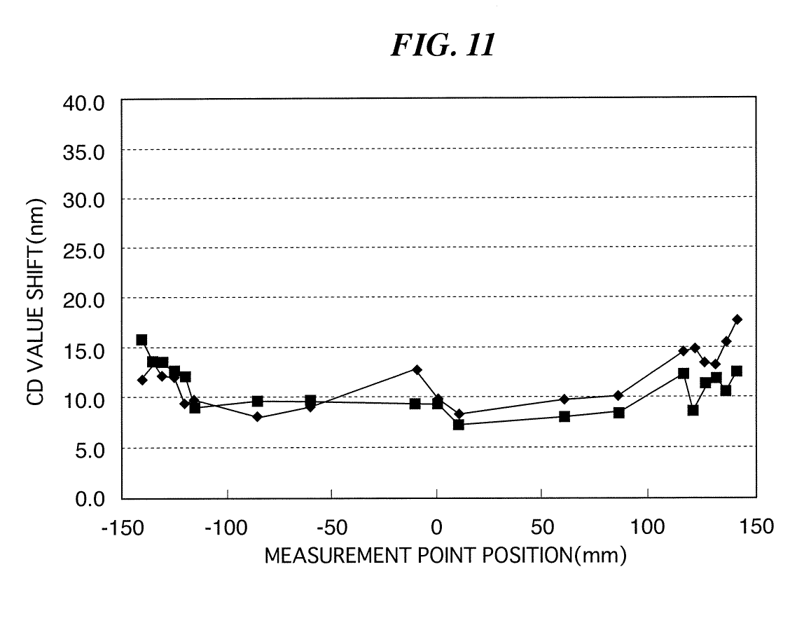

The CD value shift was then calculated for each of the measurement points, and plotted on the graph of FIG. 11. Here, “♦” again indicates the CD value shifts for the measurement points along the x-direction, and “▪” indicates the CD value shifts for the measurement points along the y-direction.

### Example 5

Etching of the ARC layer 68 and the polysilicon layer 67, and ashing of the krypton fluoride resist layer 69 and so on were carried out as in Example 3. In the present Example, however, in each of the etching of the ARC layer 68 and the polysilicon layer 67, and the ashing of the krypton fluoride resist layer 69 and so on, the processing gas was jetted into the processing space S from only the central portion processing gas introducing hole group of the processing gas introducing nozzle 38.

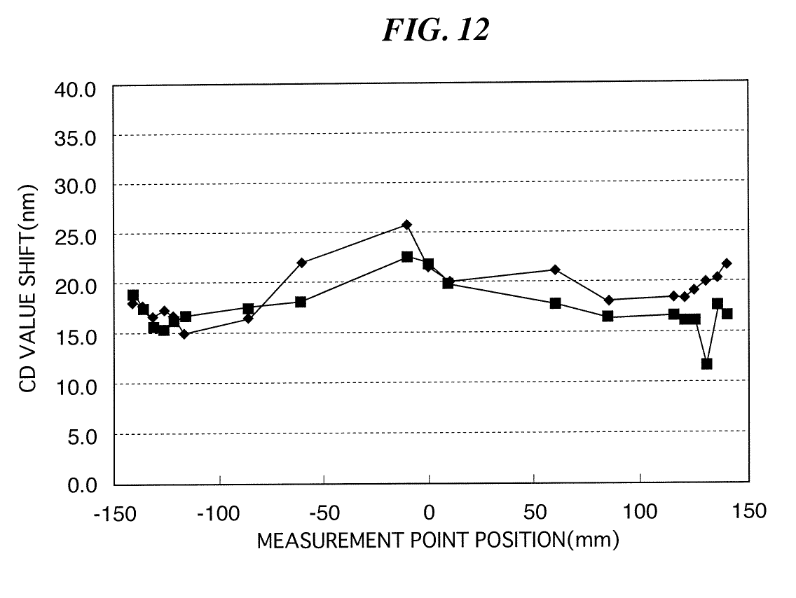

The CD value shift was then calculated for each of the measurement points, and plotted on the graph of FIG. 12. Here, “♦” again indicates the CD value shifts for the measurement points along the x-direction, and “▪” indicates the CD value shifts for the measurement points along the y-direction.

From the graphs of FIGS. 10, 11, and 12, it was found that if the processing gas is jetted into the processing space S from only the peripheral portion processing gas introducing hole group, then the CD value shift decreases in a central portion of the wafer, whereas if the processing gas is jetted into the processing space S from only the central portion processing gas introducing hole group, then the CD value shift increases in the central portion of the wafer. That is, it was found that the distribution of the CD value shift over the wafer can be controlled by changing the processing gas jetting method for the processing gas introducing nozzle 38.

Next, the respective CD value shifts due to the etching were investigated in the plasma processing apparatus 10 and a plasma processing apparatus having a conventional shower head. Unlike Examples 3 to 5, the investigated CD value shifts included not only the difference between the width of the lowermost portion of the krypton fluoride resist layer 69 and that of the polysilicon layer 67 (“Bottom CD”) but also the difference between the width of the topmost portion of the krypton fluoride resist layer 69 before etching (FIG. 9A) and the width of the topmost portion of the polysilicon layer 67 after etching (FIG. 9B) (“Top CD”) as well as the difference between the width of the middle portion of the krypton fluoride resist layer 69 before etching (FIG. 9A) and the width of the middle portion of the polysilicon layer 67 after etching (FIG. 9B) (“Middle CD”).

### Example 6

First, a wafer was provided, on which surface the krypton fluoride resist layer 69 corresponding to sparse (ISO) etching patterns is formed. The width of the lowermost portion, middle portion and topmost portion of the krypton fluoride resist layer 69 on the wafer was measured at a plurality of measurement points on the wafer surface.

After that, in the plasma processing apparatus 10, the ARC layer 68 was etched, the polysilicon layer 67 was etched, and the krypton fluoride resist layer 69 and the ARC layer 68 immediately below the krypton fluoride resist layer 69 were ashed under the similar conditions as in Example 3.

In the present Example, in each of the etching of the ARC layer 68 and the polysilicon layer 67, and the ashing of the krypton fluoride resist layer 69 and so on, the processing gas was jetted into the processing space S from both the central portion processing gas introducing hole group and the peripheral portion processing gas introducing hole group of the processing gas introducing nozzle 38.

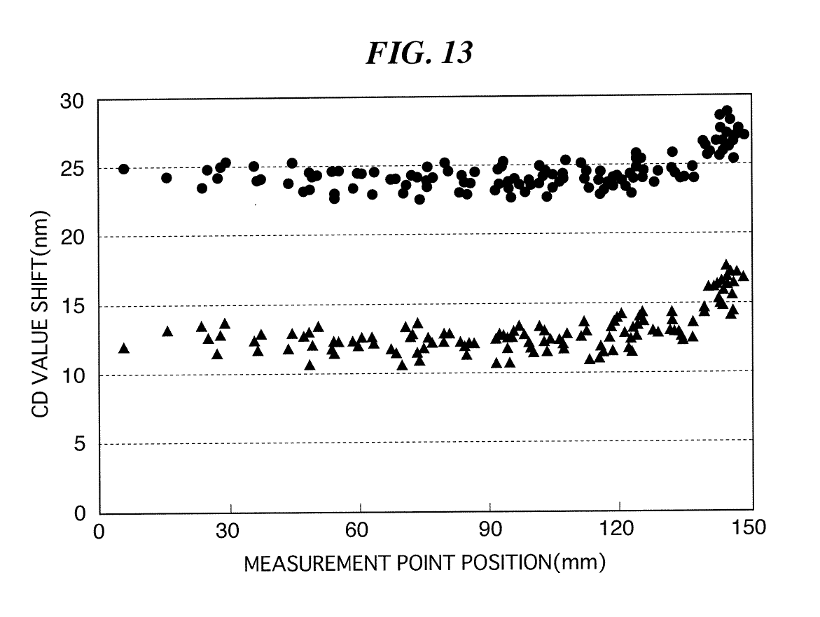

Next, the width of the lowermost portion, middle portion and topmost portion of the polysilicon layer 67 on the etched wafer was measured at the plurality of measurement points on the wafer surface. After that, the CD value shift was calculated for each of the measurement points, and particularly the shifts of the middle portion were plotted on the graph of FIG. 13 and indicated by “▴”. Here, the axis of abscissas indicates the distance of each measurement point from the center of the wafer.

In addition, three-sigma (the standard deviation multiplied by 3) of the CD value shifts in the lowermost portion, middle portion and topmost portion in the present Example is shown in Table 1 as described below.

### Example 7

First, a wafer was provided, on which surface the krypton fluoride resist layer 69 corresponding to dense (NEST) etching patterns is formed. The width of the lowermost portion, middle portion and topmost portion of the krypton fluoride resist layer 69 on the wafer was measured at a plurality of measurement points on the wafer surface.

After that, in the plasma processing apparatus 10, the ARC layer 68 was etched, the polysilicon layer 67 was etched, and the krypton fluoride resist layer 69 and the ARC layer 68 immediately below the krypton fluoride resist layer 69 were ashed under the similar conditions to Example 3.

Also in the present Example, in each of the etching of the ARC layer 68 and the polysilicon layer 67, and the ashing of the krypton fluoride resist layer 69 and so on, the processing gas was jetted into the processing space S from both the central portion processing gas introducing hole group and the peripheral portion processing gas introducing hole group of the processing gas introducing nozzle 38.

Next, the width of the lowermost portion, middle portion and topmost portion of the polysilicon layer 67 on the etched wafer was measured at the plurality of measurement points on the wafer surface. After that, the CD value shift was calculated for each of the measurement points, and particularly the shifts of the middle portion were plotted on the graph of FIG. 13 and indicated by “●”.

In addition, three-sigma of the CD value shifts in the lowermost portion, middle portion and topmost portion in the present Example is also shown in Table 1 as described below.

### Comparative Example 5

First, a wafer was provided, on which surface the krypton fluoride resist layer 69 corresponding to sparse etching patterns is formed. The width of the lowermost portion, middle portion and topmost portion of the krypton fluoride resist layer 69 on the wafer was measured at a plurality of measurement points on the wafer surface.

After that, in the plasma processing apparatus having a conventional shower head, the ARC layer 68 was etched, the polysilicon layer 67 was etched, and the krypton fluoride resist layer 69 and the ARC layer 68 immediately below the krypton fluoride resist layer 69 were ashed under the similar conditions to Example 3.

In the present Example, in each of the etching of the ARC layer 68 and the polysilicon layer 67, and the ashing of the krypton fluoride resist layer 69 and so on, the processing gas was jetted into the processing space S uniformly from each gas introducing hole of the shower head.

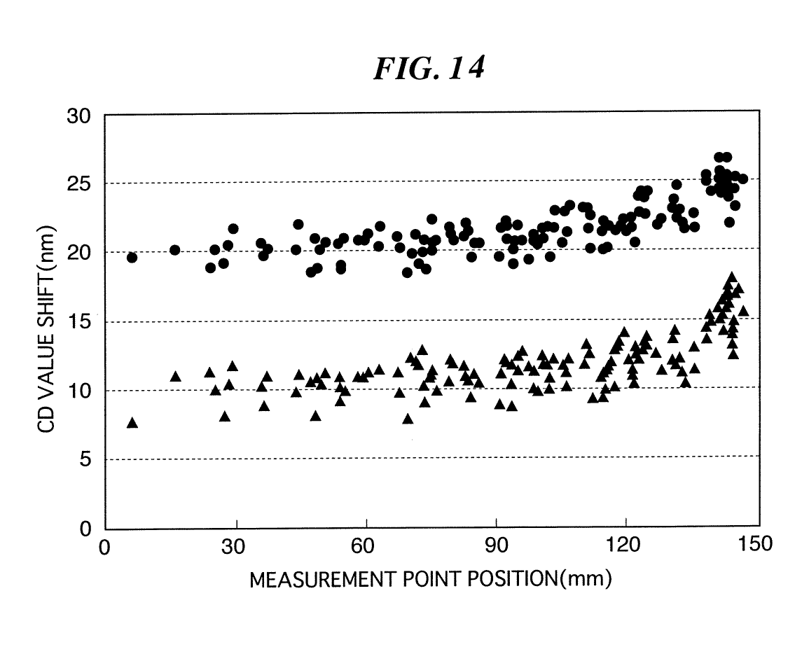

Next, the width of the lowermost portion, middle portion and topmost portion of the polysilicon layer 67 on the etched wafer was measured at the plurality of measurement points on the wafer surface. After that, the CD value shift was calculated for each of the measurement points, and particularly the shifts of the middle portion were plotted on the graph of FIG. 14 and indicated by “▴”. Here, the axis of abscissas indicates the distance of each measurement point from the center of the wafer.

In addition, three-sigma of the CD value shifts in the lowermost portion, middle portion and topmost portion in the present Example is also shown in Table 1 as described below.

### Comparative Example 6

First, a wafer was provided, on which surface the krypton fluoride resist layer 69 corresponding to dense etching patterns is formed. The width of the lowermost portion, middle portion and topmost portion of the krypton fluoride resist layer 69 on the wafer was measured at a plurality of measurement points on the wafer surface.

After that, in the plasma processing apparatus having a conventional shower head, the ARC layer 68 was etched, the polysilicon layer 67 was etched, and the krypton fluoride resist layer 69 and the ARC layer 68 immediately below the krypton fluoride resist layer 69 were ashed under the similar conditions to Example 3.

Also in the present Example, in each of the etching of the ARC layer 68 and the polysilicon layer 67, and the ashing of the krypton fluoride resist layer 69 and so on, the processing gas was jetted into the processing space S uniformly from the gas introducing holes of the shower head.

Next, the width of the lowermost portion, middle portion and topmost portion of the polysilicon layer 67 on the etched wafer was measured at the plurality of measurement points on the wafer surface. After that, the CD value shift was calculated for each of the measurement points, and particularly the shifts of the middle portion were plotted on the graph of FIG. 14 and indicated by “●”.

In addition, three-sigma of the CD value shifts in the lowermost portion, middle portion and topmost portion in this Example is also shown in Table 1 as described below.

TABLE 1

| | | Top CD | Middle CD | Bottom CD |
|---|---|---|---|---|
| | Etched Patterns | (nm) | (nm) | (nm) |
| Example 6 | ISO (Sparse) | 8.4 | 5.2 | 3.9 |
| Comparative | | 9.0 | 6.9 | 7.0 |
| Example 5 | | | | |
| Example 7 | NEST (Dense) | 5.0 | 4.1 | 4.3 |
| Comparative | | 6.3 | 5.6 | 5.4 |
| Example 6 | | | | |

As a result of the comparison between the graph of FIG. 13 and the graph of FIG. 14, and from the Table 1, it was found that the variation of the CD value shifts in the plasma processing apparatus 10 is smaller than the variation of the CD value shifts in the plasma processing apparatus having a conventional shower head. Therefore, it was found that the variation of the CD value shifts can be suppressed by using the processing gas introducing nozzle 38 to jet out the processing gas from a single point into the processing space S.

What is claimed is:

1. A substrate processing apparatus for carrying out etching as plasma processing on a substrate, comprising a processing chamber in which the substrate is housed, a stage that is disposed in said processing chamber and on which the substrate is mounted, and at least one processing gas introducing unit that introduces a processing gas into said processing chamber;
wherein said processing gas introducing unit is a projecting body that projects out into said processing chamber, and has therein a plurality of processing gas introducing holes that open out in different directions to one another.

2. A substrate processing apparatus as claimed in claim 1, wherein said processing gas introducing holes are divided into at least two processing gas introducing hole groups; and
a flow rate of the processing gas introduced into said processing chamber is controlled independently for each of said processing gas introducing hole groups.

3. A substrate processing apparatus as claimed in claim 1, wherein said processing gas introducing unit has a tip that is a hemispherical projecting body.

4. A substrate processing apparatus as claimed in claim 3, wherein said processing gas introducing holes are divided into a first processing gas introducing hole group and a second processing gas introducing hole group;
said first processing gas introducing hole group comprises ones of said processing gas introducing holes that open out within a region surrounded by a line of intersection where a cone that has its apex as a center of the hemisphere and broadens out toward said stage intersects with a surface of the hemisphere; and
said second processing gas introducing hole group comprises ones of said processing gas introducing holes that are not included in said first processing gas introducing hole group.

5. A substrate processing apparatus as claimed in claim 4, wherein the cone has an apex angle in a range of 120°±2°.

6. A substrate processing apparatus as claimed in claim 3, wherein said processing gas introducing unit has an outer structure including a surface of the hemisphere, and an inner structure enclosed by said outer structure.

7. A substrate processing apparatus as claimed in claim 1, wherein the substrate has a polysilicon layer, and said etching etches the polysilicon layer.

8. A substrate processing method implemented by a substrate processing apparatus for carrying out etching as plasma processing on a substrate, including a processing chamber in which the substrate is housed, and at least one processing gas introducing unit that introduces a processing gas into the processing chamber, wherein the processing gas introducing unit is a projecting body that projects out into the processing chamber, and has therein a plurality of processing gas introducing holes that open out in different directions to one another, the processing gas introducing holes being divided into at least two processing gas introducing hole groups; the substrate processing method comprising:
independently controlling a flow rate of the processing gas introduced into the processing chamber by each of the processing gas introducing hole groups.
